(19) United States
(12) Patent Application Publication
(10) Pub. No.: US 2006/0115980 A1
(43) Pub. Date: Jun. 1, 2006

(54) Method for decreasing a dielectric constant of a low-k film

(75) Inventors: Chung-Chi Ko, Nantou (TW); Lih-Ping Li, Hsinchu (TW); Lain-Jong Li, Hsin-Chu (TW); Syun-Ming Jang, Hsinchu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/130,044

(22) Filed: May 16, 2005

Related U.S. Application Data
(60) Provisional application No. 60/631,744, filed on Nov. 30, 2004.

(51) Int. Cl. H01L 21/4763

(52) U.S. Cl. 438/637

(57) ABSTRACT

A method of forming a low dielectric constant film that can be used in a damascene process is disclosed. An organosilicon precursor such as octamethylcyclotrisiloxane (OMCTS) or any other compound that contains Si, C, and H and optionally O is transported into a PECVD chamber with a carrier gas such as CO or CO₂ to provide a soft oxidation environment that leads to a higher carbon content and low k value in the deposited film. The carrier gas may replace helium or argon that have a higher bombardment property that can damage the substrate. Since CO and CO₂ can contribute carbon to the deposited film, a lower k value is achieved than when an inert carrier gas is employed. The deposited film can be employed, for example, as a dielectric layer in a damascene stack or as an etch stop layer.

### CROSS-REFERENCE

This application claims priority from U.S. Provisional patent application Ser. No. (Attorney Docket No. 24061.392), filed on Nov. 30, 2004, and entitled “A METHOD FOR DECREASING A DIELECTRIC CONSTANT OF A LOW-K FILM”.

### BACKGROUND

The manufacture of integrated circuits in a semiconductor device involves the formation of a sequence of layers that are categorized by their location in the front end of the line (FEOL) or in the back end of the line (BEOL). In BEOL processing, metal interconnects and vias form horizontal and vertical connections between layers and these metal lines are separated by insulating or dielectric materials to prevent capacitive coupling. As the dimensions of the wiring and the intermetal distances have steadily decreased in order to satisfy a constant demand for higher performance in electronic devices, the challenge to prevent crosstalk between the metal lines has become increasingly important.

Recent efforts in semiconductor manufacturing have generally centered on decreasing the resistivity of metal wiring used for via and interconnects by switching from aluminum to copper and reducing the dielectric constant of the insulating or dielectric materials between the conductive layers. For more advanced technologies, such as the 100 nm and 130 nm technology nodes, new materials are needed to improve upon a dielectric constant (k) of about 4 for SiO₂.

Dielectric layers are often deposited on a substrate by a plasma enhanced chemical vapor deposition (PECVD) method in which a gas mixture is directed into a chamber where plasma is formed by the application of radio frequency (RF) power. The substrate and reaction zone are usually heated to promote the chemical reaction and increase the rate of formation of the dielectric film on the substrate. When forming an inorganic oxide like SiO₂, a silicon source gas such as silane (SiH₄) may be used with an oxidizing gas like O₂. A third component such as an inert carrier gas (e.g., He, N₂ or Ar) may also be employed. For silicon oxides containing carbon, a source gas containing silicon and carbon is required or a gas containing silicon can be mixed with a gas containing carbon. In either case, an oxidizing gas like O₂ may be added to the mixture. A carrier gas is frequently used to help transport a viscous liquid such as a silicon precursor with a boiling point of about 100° C. or higher into the PECVD chamber.

Referring to FIG. 1, a dual damascene structure is widely used in BEOL processing and involves forming a trench and via hole in a stack of layers and then depositing a metal to simultaneously fill the trench and via. A chemical mechanical polish (CMP) step planarizes a metal 19 so that it is level with a top layer 17 of the dielectric stack as shown in FIG. 1. Besides dielectric layers 14 and 16, other layers in the damascene stack may include a passivation or etch stop layer 17 which serves as an etch stop for the CMP step, an etch stop layer 15 between the first dielectric layer 14 and second dielectric layer 16, and a barrier layer 13 separating a metal layer 12 and substrate 10 from the first dielectric layer 14. However, a “non-etch stop” dual damascene approach may be used in which etch stop layer 15 is omitted so that dielectric layers 14, 16 become a single dielectric layer. Generally, all non-conducting layers in the damascene stack are insulated to prevent capacitive coupling between the wiring.

Some recent innovations involving low k dielectric materials use a film of parylene on a substrate. The k value of the deposited material is between 2.2 and 2.4 and it has a high thermal stability of at least 350° C. to 400° C. that is needed for permanent layers in a device. However, parylene does not have good etch resistance and requires a special apparatus to crack the starting material and form a reactive monomer. Some processes overcome the poor etch qualities of the parylene polymer by introducing a copolymer that contains silicon. In addition, the xylylene copolymer has thermally labile groups that produce microscopic gas pockets at an elevated curing temperature which further lowers the k value. The formation of the reactive organic species still requires a special tube reactor where a catalytic dissociation of a starting material occurs.

A SiOF layer has been proposed as a low k dielectric material but suffers from a hydrophilic property in which water is absorbed over time, and this change results in a shift to higher dielectric constants as time elapses. One possible solution involves carefully controlling the ratio of the gas composition that includes C₂F₆, tetraethylorthosilicate (TEOS), and O₂.

Other improvements in low k dielectric materials involve a silicon source gas having at least one C—Si—H linkage, an oxidizing gas like N₂O or O₂, and an inert carrier gas that are deposited in a PECVD chamber to form a silicon oxide layer containing up to 20% carbon. The carbon content helps to protect the conductive layers from moisture and also reduces k compared to SiO₂. This low k layer is annealed at low pressure and high temperature to stabilize its properties.

Another low k silicon oxide layer containing carbon and hydrogen is preferably formed from silicon precursors comprising Si, C, O, and H and having ring structures. The SiCOH layer is thermally stable to 350° to 400° C. An inert carrier gas such as He or Ar may be used.

### BRIEF DESCRIPTION OF THE DRAWINGS

FIG. 1 is a cross sectional view depicting a dual damascene structure after planarization of the metal that is used to fill the via and trench.

FIGS. 2a-2e are cross sectional views showing formation of a dual damascene structure using low k dielectric layers.

FIGS. 3a-3d are cross sectional views showing formation of a dual damascene structure having etch stop layers.

### DETAILED DESCRIPTION

It is to be understood that the following disclosure provides many different embodiments, or examples, for implementing different features of various embodiments. Specific examples of components and arrangements are described below to simplify the present disclosure. These are merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

One concern associated with the use of inert gases like He is that they generate plasma characterized as having a high bombardment property that may damage the underlying substrate and film itself. When He is used to deposit a silicon oxide layer containing carbon, the carbon content is lower compared to a process not utilizing an inert carrier gas which results in a higher k value of the dielectric layer. Accordingly, a carrier gas that generates plasma with less bombardment is needed. In addition, a carrier gas that does not increase the resulting k value of the dielectric layer is desired. Such a carrier gas that can decrease the k value of the dielectric material may be employed in a process such as PECVD.

Another improvement needed in techniques such as PECVD is to apply a method that will decrease the rate of oxidation of a silicon starting material and thereby enable a higher carbon content and lower k value in the resulting dielectric layer. When O₂ is used as the oxidizing gas with a SiO_{X}C_{Y}H_{Z} reactant, the oxidation rate is high and typically a low carbon content is achieved in the deposited material. An alternate oxidizing gas that enables a “softer” oxidation and higher carbon content in the dielectric layer is needed.

The present disclosure is particularly useful in forming a low k dielectric layer in a single or dual damascene structure, although it is not limited to such structures. The PECVD deposited material may be used as a dielectric layer, but can also perform other functions, such as serving as an etch stop layer or a barrier layer. A method is used to form a layer containing Si, O, C, and H that has a low k value, good etch properties, and can be readily implemented at low cost in a manufacturing line.

To achieve this, an oxidized organosilicon layer is formed by plasma assisted oxidation of an organosilicon compound using a carrier gas that does not have a high bombardment property. A RF power in the range of about 100 Watts to about 1000 Watts is applied to promote the deposition on a substrate in the PECVD chamber. The chamber may also be heated to approximately 150° C. to 400° C. to increase the rate of reaction between an oxidizing gas and the organosilicon compound. Preferably, the carrier gas is the same as the oxidizing gas when CO, CO₂, or N₂O are employed in the deposition. However, CO and CO₂ provide the added benefit of contributing carbon to the dielectric layer, which results in a lower k value than when an oxidizing gas not containing carbon is used. The higher carbon content in the deposited film associated with a CO or CO₂ carrier and oxidizing gas is believed to be partly due to a soft oxidation in which the organosilicon compound is more slowly oxidized than when O₂ is used as the oxidizing gas. Likewise, N₂O as a carrier and oxidizing gas provides a softer oxidation of organosilicon compounds than O₂ but does not yield k values in the resulting deposited layer as low as those achieved with CO or CO₂. When the carrier gas is N₂, O₂ may be added as an oxidizing gas. In this case, the high bombardment property of helium is avoided but the oxidation reaction is not slowed as when CO, CO₂ or N₂O are employed as carrier and oxidizing gases.

The oxidizing gas becomes dissociated when a RF power is applied to the chamber and a highly reactive species results. A constant RF power can be applied or the RF power may be pulsed to reduce heating of the substrate and to favor a higher porosity in the deposited film. A higher porosity generally leads to a lower k value since the dielectric constant of air is 1 in the free space within the dielectric layer.

Organosilicon compounds that are useful in the present invention are characterized as materials having a boiling point in the range of about 30° C. to about 200° C. and comprised of at least one C—Si bond. The compounds may or may not contain oxygen. These materials include but are not limited to the following compounds: hexamethyldisilane [(CH₃)₃SiSi(CH₃)₃]; hexamethyldisiloxane [(CH₃)₃SiOSi(CH₃)₃]; methoxytrimethylsilane [(CH₃OSi(CH₃)₃]; methyltrimethoxysilane [(CH₃O)₃Si(CH₃)]; dimethoxydimethylsilane [(CH₃)₂Si(OCH₃)₂], tetraethylsilane [(CH₃CH₂)₄Si]; tetramethylsilane [(CH₃)₄Si]; and octamethylcyclotrisiloxane or OMCTS which has the ring structure.

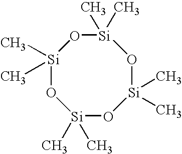

The following are examples of the deposition of low k films with an OMCTS precursor. The precursor is transported into the PECVD chamber using a carrier gas. Unless otherwise noted, the carrier gas is the same as the oxidizing gas. The temperature of the substrate in the chamber was maintained at 150° C. to 400° C. and the thickness of the resulting layer is in a range of about 3800 Angstroms to about 10000 Angstroms.

### EXAMPLE 1

In this example, plasma was generated in a continuous mode during film deposition. Reactor pressure was maintained at 2 to 8 Torr and the substrate was placed on an electrode to which a RF power of 100 to 1000 Watts was applied at a frequency of 13.86 MHz. OMCTS was transported into the reactor with a carrier gas comprising CO at a flow rate of between 100 and 1000 standard cubic centimeters per minute (sccm). The resulting dielectric layer had a dielectric constant k<2.55 in the as deposited condition.

### EXAMPLE 2

In this example, a plasma was generated in a continuous mode during film deposition. Reactor pressure was maintained at 2 to 8 Torr and the substrate was placed on an electrode to which a RF power of 100 to 1000 Watts was applied at a frequency of 13.86 MHz. OMCTS was transported into the reactor with a carrier gas comprising CO₂ at a flow rate of between 100 and 1000 sccm. The resulting dielectric layer had a dielectric constant k<2.5 in the as deposited condition.

### EXAMPLE 3

In this example, a plasma was generated in a continuous mode during film deposition. Reactor pressure was maintained at 2 to 8 Torr and the substrate was placed on an electrode to which a RF power of 100 to 1000 Watts was applied at a frequency of 13.86 MHz. OMCTS was transported into the reactor with a carrier gas comprising N₂O at a flow rate of between 100 and 1000 sccm. The resulting dielectric layer had a dielectric constant k<2.55 in the as deposited condition.

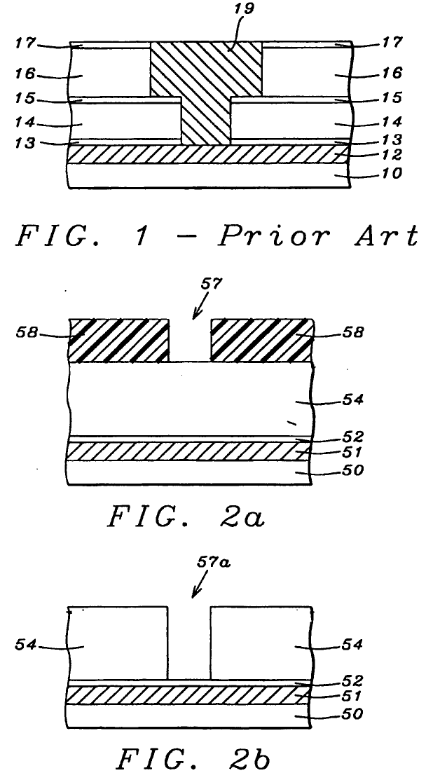

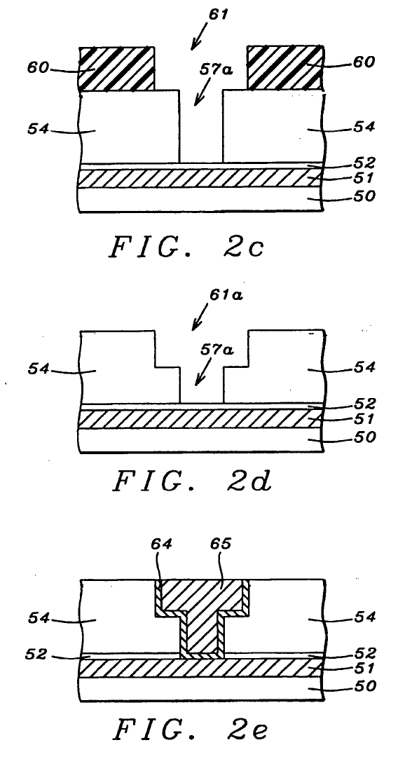

In one embodiment, the low k dielectric films of the present disclosure are incorporated in a dual damascene structure as illustrated in FIGS. 2a-2e. The figures are not necessarily drawn to scale. Referring to FIG. 2a, a substrate 50 which is typically silicon is provided upon which a conductive layer 51 is deposited. The conductive layer 51 can be copper, aluminum, a Cu/Al alloy or other metals. Conductive layer 51 is generally contained within an insulating layer (not shown) and the conductive layer may have a barrier layer (not shown) between the metal and the adjacent insulating layer. An etch stop layer or barrier layer 52 comprised of an oxide, carbide, or nitride such as Si₃N₄ is then deposited on conductive layer 51.

A dielectric layer 54 with a thickness in the range of about 3800 Angstroms to about 10000 Angstroms is then formed on etch stop 52 by a PECVD technique according to a method of the present disclosure. For example, the process described in EXAMPLE 1, EXAMPLE 2, or EXAMPLE 3 may be used here. However, OMCTS may be replaced as the organosilicon source gas with a compound that may or may not contain oxygen but has at least one C—Si bond. The dielectric layer 54 is comprised of silicon, carbon, oxygen and hydrogen and has a low k value. In addition, damage to the underlying layers 52 and 51 is avoided by using a carrier gas having a low bombardment property rather than a high bombardment property associated with helium or argon in conventional CVD methods. A low k value is achieved in film 54 because preferably CO or CO₂ are used as carrier gas and these gases contribute carbon to film 54 which helps to reduce the dielectric constant k. Moreover, a softer oxidation with CO, CO₂ or N₂O is realized than when O₂ is the oxidizing gas, which thereby enables a higher carbon content and lowers the k value relative to a Si—O—C—H layer formed by a conventional method. Optionally, O₂ may be used as an oxidizing gas when CO, CO₂ or N₂O is the carrier gas. However, the k value of the resulting film may not be as low as when O₂ is omitted.

A photoresist layer 58 is coated, baked and patterned to form an opening 57 in FIG. 2a. Opening 57 is transferred through underlying layers 54. Photoresist 58 is removed by a wet strip or other method after the etch transfer is complete. Another photoresist 60 is coated on passivation layer 54, baked and patterned to form opening 61 in FIG. 2c. Opening 61 is etch transferred through into dielectric layer 54 to form a trench opening 61a. Then a barrier layer 64 that lines the sidewalls and bottom of trench 61a and via hole 57a is deposited. Barrier layer 64 is comprised of materials such as TaN, TiN, WN, or TaSiN that prevent moisture in dielectric layer 54 or etch stop layer 56 from attacking the metal 65 which is deposited in the trench 61a and via hole 57a. Metal 65, which is typically copper or aluminum or an alloy of one of the aforementioned metals, is deposited by an electroplating, CVD, sputtering or evaporation technique. Then a CMP step is used to lower the level of the metal 65 until it is coplanar with etch stop layer 56 as illustrated in FIG. 2e.

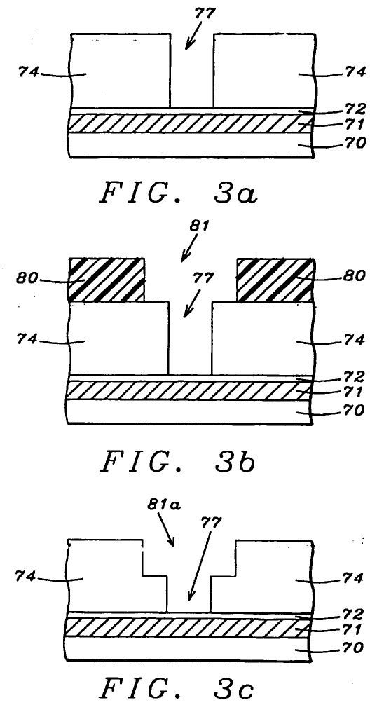

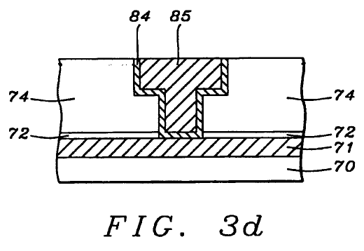

In another embodiment, the low k dielectric layer of the present disclosure is incorporated as an etch stop layer in a dual damascene structure as illustrated in FIGS. 3a-3d. Referring to FIG. 3a, a substrate 70 which is typically silicon is provided upon which a conductive layer 71 has been deposited. The conductive layer 71 can be copper, aluminum, a Cu/Al alloy or a metal silicide. Conductive layer 71 is generally contained within an insulating layer (not shown) and the conductive layer may have a barrier layer (not shown) between the metal and the adjacent insulating layer.

An etch stop layer 72 deposited by a PECVD method such as described in EXAMPLE 1, EXAMPLE 2, or EXAMPLE 3 is then formed with a thickness in the range of about 300 to about 1000 Angstroms. However, OMCTS may be replaced as the organosilicon source gas with a compound that may or may not contain oxygen but has at least one C—Si bond. The carrier and oxidizing gas during the deposition is preferably CO or CO₂ in order to increase the carbon content in the deposited film comprised of silicon, carbon, oxygen, and hydrogen and to achieve a lower k value. However, N₂O or N₂ may also be used as carrier gas. When N₂ is the carrier gas, oxygen may be added as an oxidizing gas. Optionally, O₂ may be used as an oxidizing gas when CO, CO₂ or N₂O is the carrier gas. However, the k value of the resulting film may not be as low as when O₂ is omitted. The carbon content in the etch stop 72 prevents moisture from diffusing from an overlying dielectric layer into conductive layer 71. The silicon and oxygen content in etch stop 72 provide good etch resistance and high selectivity during an oxygen plasma etch. In addition, damage to the underlying layers 70, 71 is avoided by using a carrier gas having a low bombardment property rather than the high bombardment property associated with helium or argon in conventional CVD methods.

A dielectric layer 74 is deposited on etch stop 72 and is formed from a group of materials such as polyimides, fluorosilicate glass (FSG), borosilicate glass, SiO₂, polysilsesquioxanes, FLARE from Allied Signal, SiLK from Dow Corning and other low k materials. Dielectric layer 74 is generally from about 3800 to 10000 Angstroms thick and is deposited by CVD, PECVD, or a spin on technique in the case of pure organic materials like polyimides and polysilsesquioxanes.

Referring to FIG. 3a, a via hole 77 is formed in layer 74 by patterning a photoresist layer (not shown) and using the layer as an etch mask during a pattern transfer step. A photoresist 80 is coated on dielectric layer 74, baked and patterned to form an opening 81 as shown in FIG. 3b. The opening is transferred partially through dielectric layer 74 to form a trench 81a using an etch process that stops on etch stop 72. The remaining photoresist 80 is removed by a stripping process to produce the trench 81a and via hole 77 shown in FIG. 3c.

A barrier layer 84 is deposited on the sidewalls and bottom of trench 81a and via 77. Barrier layer 84 is comprised of materials such as TaN, TiN, WN, or TaSiN. The final steps which complete the dual damascene structure are deposition of a metal 85 that fills the trench 81a and via hole 77 and a CMP step that lowers the level of metal 85 until it is coplanar with dielectric layer 74 as depicted in FIG. 3d.

The application of the low k dielectric material formed by an improved PECVD technique has been demonstrated in the above description which is intended as an example and not as limiting the scope of the disclosure. Accordingly, the low k dielectric material may potentially be used in any non-conducting layer. Replacement of an inert carrier gas during the deposition of the layer containing Si, O, C and H with CO, CO₂ or N₂O avoids potential damage to dielectric layer 74 caused by a high bombardment property of He or Ar. Replacement of oxygen as the oxidizing gas with CO, CO₂ or N₂O provides a softer oxidation that enables a higher carbon content that may be needed for advanced technologies such as the 100 nm and 130 nm nodes. The PECVD of the present disclosure has the added advantage in that it is readily implemented in manufacturing since no new tools are needed. The preferred gases CO and CO₂ are commercially available and can be easily supplied to existing PECVD chambers. Furthermore, the organosilicon precursor gas OMCTS is readily available and can be employed in existing tools.

The foregoing has outlined features of several embodiments according to aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. A method of forming a low k dielectric layer in a dual damascene structure comprising:
providing a substrate,
positioning the substrate in a processing chamber,
flowing a precursor gas comprising Si, C, and H into the chamber, wherein the precursor gas is transported with a carrier gas, wherein the carrier gas is a carbon containing gas, and
depositing a film comprising Si, C, and O on the substrate.

2. The method of claim 1 wherein the precursor gas includes oxygen.

3. The method of claim 1 wherein the deposited film includes H.

4. The method of claim 1 wherein a RF power is provided by a mixed frequency power source.

5. The method of claim 4 wherein the RF power is between about 100 Watts and 1000 Watts and is applied at a frequency of approximately 13.86 MHz.

6. The method of claim 4 wherein the RF power is applied in a continuous mode.

7. The method of claim 4 wherein the RF power is applied in a pulsed mode.

8. The method of claim 1 wherein the precursor gas is selected from a group including but not limited to tetraethylsilane, tetramethylsilane, hexamethyldisilane, hexamethyldisiloxane, methoxytrimethylsilane, methyltrimethoxysilane, dimethoxydimethylsilane, and octamethylcyclotetrasiloxane.

9. (canceled)

10. The method of claim 1 wherein the carbon containing gas is CO.

11. The method of claim 1 wherein the carbon containing gas is carbon dioxide.

12. The method of claim 1 wherein the carrier gas is a nitrogen containing gas.

13. The method of claim 12 wherein the nitrogen containing gas is N₂O.

14. The method of claim 12 wherein the nitrogen containing gas is N₂.

15. The method of claim 14 wherein oxygen is added as an oxidizing gas.

16. The method of claim 1 wherein the chamber is heated to a temperature in a range of about 150° C. to about 400° C. to promote the deposition.

17. A method of forming an etch stop layer with a low dielectric constant in a dual damascene structure comprising:
providing a substrate,
positioning the substrate in a processing chamber,
flowing a precursor gas comprised of Si, C, H, and optionally O into the chamber, the precursor gas is transported with a carrier gas wherein the carrier gas is a carbon containing gas, and
depositing a film consisting of Si, C, O, and optionally H on the substrate.

18. The method of claim 17 wherein the etch stop layer is formed between the substrate and a dielectric layer selected from a group of low k dielectric materials including but not limited to fluorosilicate glass, polyimides, polysilsesquioxanes, FLARE, and SiLK.

19. The method of claim 17 wherein a RF power is provided by a mixed frequency power source.

20. The method of claim 19 wherein the RF power is from between 100 Watts and 1000 Watts and is applied with a frequency of 13.86 MHz.

21. The method of claim 17 wherein a RF power is applied in a continuous mode.

22. The method of claim 17 wherein a RF power is applied in a pulsed mode.

23. The method of claim 17 wherein the precursor gas is selected from a group including but not limited to tetraethylsilane, tetra methylsilane, hexamethyldisilane, hexamethyldisiloxane, methoxytrimethylsilane, methyltrimethoxysilane, dimethoxydimethylsilane, and octamethylcyclotetrasiloxane.

24. (canceled)

25. The method of claim 17 wherein the carbon containing gas is carbon monoxide.

26. The method of claim 17 wherein the carbon containing gas is carbon dioxide.

27. The method of claim 17 wherein the carrier gas is a nitrogen containing gas.

28. The method of claim 27 wherein the nitrogen containing gas is N₂O.

29. The method of claim 27 wherein the nitrogen containing gas is N₂.

30. The method of claim 29 wherein oxygen is added as an oxidizing gas

31. The method of claim 17 wherein the chamber is heated to a temperature in a range of about 150° C. to about 400° C. to promote the deposition.

32. The method of claim 17 wherein the deposited film forms a thickness in the range of about 300 Angstroms to about 1000 Angstroms.
